(19) United States
(12) Patent Application Publication
(10) Pub. No.: US 2009/0084589 A1
(43) Pub. Date: Apr. 2, 2009

(54) LEAD TERMINAL BONDING METHOD AND PRINTED CIRCUIT BOARD

(76) Inventor: Kunihiro Tan, Hyogo (JP)

Correspondence Address: COOPER & DUNHAM, LLP, 30 Rockefeller Plaza, 20th Floor, NEW YORK, NY, 10112, US

(21) Appl. No.: 12/293,192

(22) PCT Filed: Jan. 17, 2007
(86) PCT No.: PCT/JP2008/051012

§ 371 Date: Sep. 16, 2008

(30) Foreign Application Priority Data
Jan. 22, 2007 (JP) 2007-011172

(51) Int. Cl. H05K 1/11; B23K 31/02; H05K 1/09; B23K 1/20

(52) U.S. Cl. 174/257; 228/101; 174/263; 228/161; 228/203

(57) ABSTRACT

A lead terminal bonding method includes the steps of forming a land part on a front surface of a base substrate, the land part including a metal foil; forming a metal plating layer on a surface of the land part, the metal plating layer having a Young's modulus greater than that of the metal foil; and directly bonding a metal plate to the metal plating layer by spot-welding.

### TECHNICAL FIELD

The present invention relates to a method of bonding a metal plate acting as a lead terminal to a land part of a base substrate of a printed circuit board, and a printed circuit board having a lead terminal bonded thereto by using such a method.

### BACKGROUND ART

In recent years and continuing, size-reduction and weight-reduction of electronic devices are significantly increasing. This tendency is particularly remarkable for portable devices such as mobile phones. Therefore, there is a growing desire for reducing the size of printed circuit boards with many electronic components mounted (e.g., semiconductor devices, passive components). For example, under these circumstances, a charge control circuit for controlling the charging of a secondary battery pack of a portable device is desired to be built in the battery pack. More preferably, it is desired to build the charge control circuit in the battery pack with a reduced size.

The electrodes of the secondary battery built inside the battery pack and the charge control circuit board are typically connected by a nickel plate. This is so because the nickel plate is used as wiring material for drawing electric power from the electrode of the secondary battery and is attached to the electrode of the secondary battery by spot welding. Thus, connecting the nickel plate as is to the charge control circuit board helps to remove the troublesome task of providing new wiring and contributes to size reduction of the charge control circuit board. Accordingly, the nickel plate is desired to be connected to an external connecting terminal of the charge control circuit board.

However, the following problems arise when a nickel plate is directly spot welded to a land part of a printed circuit board.

Since the land part is formed at the same time of forming a circuit pattern on the printed circuit board, the land part is formed of copper or aluminum. In a case where a nickel plate is directly spot welded to a land part formed of copper or aluminum, the nickel plate may undesirably detach from the land part due to weak bonding strength between the nickel plate and the land part. Furthermore, the area surrounding the spot welding point may be damaged due to insufficient breaking strength of the metal foil included in the land part. Therefore, a nickel plate cannot be directly spot welded to a land part of a printed circuit board.

Accordingly, Japanese Laid-Open Patent Application No. 2002-100412 discloses a method of soldering a planar nickel block to a land part on the surface of a printed circuit board and spot welding a nickel plate to the nickel block.

The method of soldering a planar nickel block to a land part on the surface of a printed circuit board and spot welding a nickel plate to the nickel block has a problem of cost increase due to the use of the nickel block and the soldering step. Furthermore, adjustment when performing the spot welding step is difficult since the heat of the spot welding may melt the solder bonding the nickel block to the land part and cause the solder to scatter. Moreover, size-reduction of the printed circuit board becomes limited by using this method.

Besides the method of soldering a nickel block, there is also a method of directly soldering a nickel plate to a land part. However, due to the difficulty in automating the soldering step, this method requires the soldering step to be performed by a person. This results in an increase of manufacturing cost.

### DISCLOSURE OF INVENTION

The present invention may provide a lead terminal bonding method and a printed circuit board that substantially obviate one or more of the problems caused by the limitations and disadvantages of the related art.

Features and advantages of the present invention are set forth in the description which follows, and in part will become apparent from the description and the accompanying drawings, or may be learned by practice of the invention according to the teachings provided in the description. Objects as well as other features and advantages of the present invention will be realized and attained by a lead terminal bonding method and a printed circuit board particularly pointed out in the specification in such full, clear, concise, and exact terms as to enable a person having ordinary skill in the art to practice the invention.

To achieve these and other advantages and in accordance with the purpose of the invention, as embodied and broadly described herein, an embodiment of the present invention provides a lead terminal bonding method including the steps of: a) forming a land part on a front surface of a base substrate, the land part including a metal foil; b) forming a metal plating layer on a surface of the land part, the metal plating layer having a Young's modulus greater than that of the metal foil; and c) directly bonding a metal plate to the metal plating layer by spot-welding.

Furthermore, another embodiment of the present invention provides a printed circuit board including: a base substrate; a land part formed on at least on a front surface of the base substrate, the land part including a metal foil; a metal plating layer formed on a surface of the land part, the metal plating layer having a Young's modulus greater than that of the metal foil; and a metal plate directly bonded to the metal plating layer by spot-welding.

Other objects, features and advantages of the present invention will become more apparent from the following detailed description when read in conjunction with the accompanying drawings.

### BRIEF DESCRIPTION OF DRAWINGS

FIG. 1A is a plan view of a printed circuit board according to a first embodiment of the present invention;

FIG. 1B is a cross-sectional view of the printed circuit board according to the first embodiment of the present invention taken along line A-A of FIG. 1A;

FIG. 2A is a plan view of a printed circuit board according to a second embodiment of the present invention;

FIG. 2B is a cross-sectional view of the printed circuit board according to the second embodiment of the present invention taken along line B-B of FIG. 2B;

FIG. 3A is a plan view of a modified example of the printed circuit board according to the first embodiment of the present invention;

FIG. 3B is a cross-sectional view of the modified example of the printed circuit board according to the first embodiment of the present invention taken along line C-C of FIG. 3A; and

FIG. 4A is a plan view of a modified example of the printed circuit board according to the second embodiment of the present invention; and

FIG. 4B is a cross-sectional view of the modified example of the printed circuit board according to the second embodiment of the present invention taken along line D-D of FIG. 4A.

### BEST MODE FOR CARRYING OUT THE INVENTION

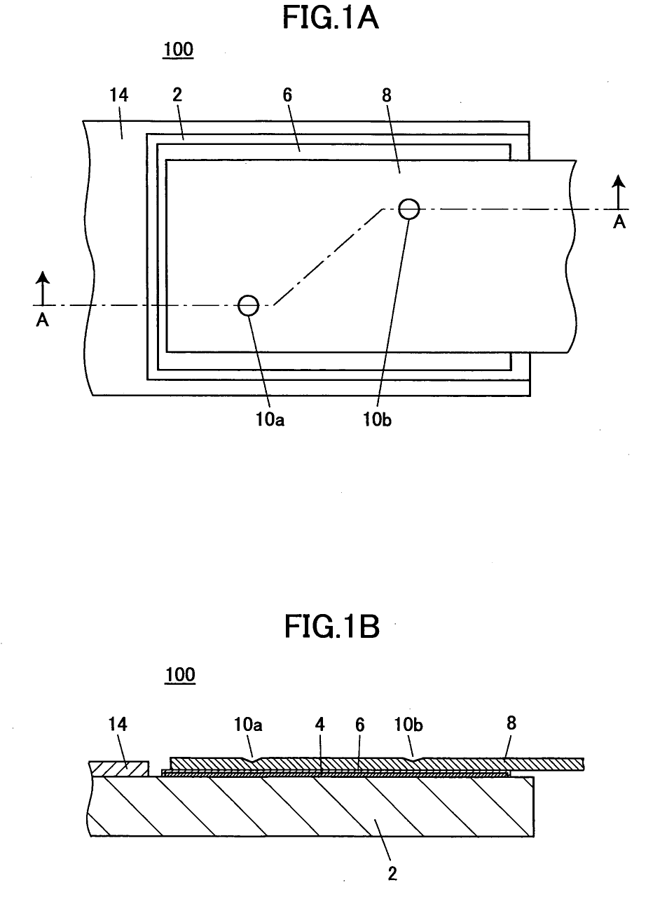

FIGS. 1A and 1B are drawings for describing a printed circuit board 100 according to a first embodiment of the present invention. FIG. 1A is a plan view of the printed circuit board 100 according to the first embodiment of the present invention. FIG. 1B is a cross-sectional view of the printed circuit board 100 according to the first embodiment of the present invention. In the printed circuit board 100 according to an embodiment of the present invention, a metal foil (e.g., copper) is laminated on a surface of an insulating base substrate 2 (e.g., glass epoxy substrate) and is patterned, to thereby form a circuit pattern and a land part 4 on the surface of the base substrate 2. For the sake of convenience, only the land part 4 is illustrated in FIGS. 1A and 1B and the circuit pattern is omitted.

The surface of the land part 4 is covered by a plating layer 6. The plating layer 6 is formed, for example, by an electrolytic plating method or a non-electrolytic plating method. The plating layer 6 includes a gold plating layer and a nickel plating layer formed on the surface of the gold plating layer. It is to be noted that the plating layer 6 is illustrated as a single layer in FIGS. 1A and 1B for the sake of convenience. A metal plate 8 including, for example, nickel or a nickel alloy is bonded onto the plating layer 6 by spot-welding. The metal plate 8 bonded to the plating layer 6 acts as a lead terminal.

In FIG. 1B, reference numerals 10a and 10b indicate the areas (points) on which spot-welding is performed. In this embodiment of the present invention, spot-welding is performed on two points which are diagonally positioned with respect to the longitudinal direction of the metal plate 8. It is to be noted that, although the area on which spot-welding is performed may be one area (point), it is preferable to performed spot-welding on two or more points for attaining a high bonding strength between the plating layer 6 and the metal plate 8.

A solder resist layer 14 having an opening(s) at the area(s) including the metal plate 8 is formed on the base substrate 2 for protecting the circuit pattern. In FIGS. 1A and 1B, the opening of the solder resist layer 14 not only contains (encompasses) the area including the metal plate 8 but also the area including the land part 4 and its surrounding area. As shown in FIG. 1A, the surface of the base substrate 2 is exposed at the area surrounding the plating layer 6 and the land part 4 where the metal plate 8 is not arranged (positioned).

The solder resist layer 14, having a height higher than the upper surface of the plating layer 6, would obstruct the bonding between the plating layer 6 and the metal plate 8 if the solder resist layer 14 is formed in the area where the metal plate 8 is situated. Therefore, it is preferable not to form the solder resist layer 14 having a height higher than the upper surface of the plating layer 6 in the area where the metal plate 8 is situated.

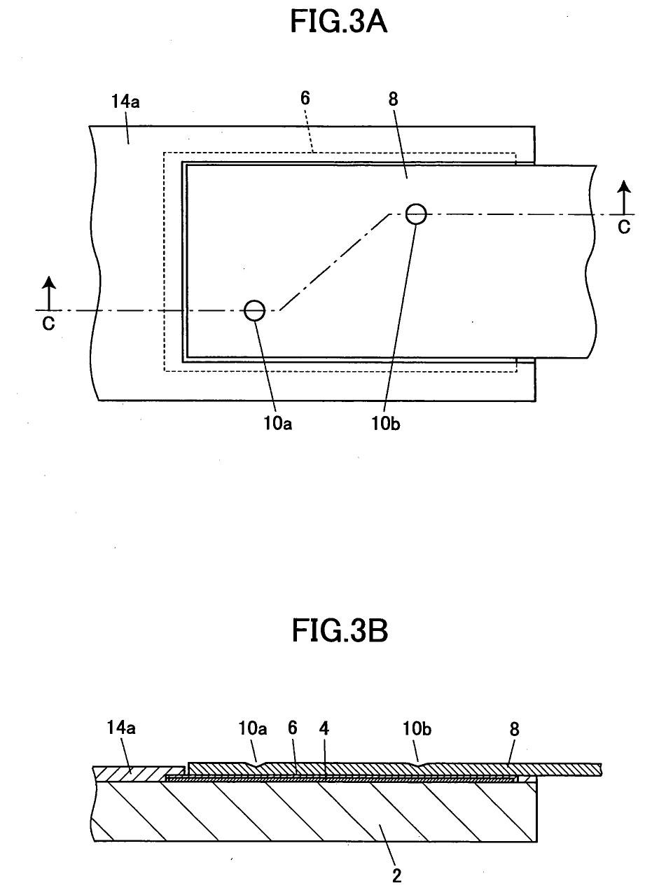

It is to be noted that a solder resist layer 14a according to another embodiment of the present invention may be formed in a manner covering substantially the entire area of the base substrate 2 except for the area where the metal plate 8 is situated, as shown in FIGS. 3A and 3B. The solder resist layer 14a according to this embodiment of the present invention can provide protection for the base substrate 2 and the land part 4 since the exposed areas of the base substrate 2 and the land part 4 can be reduced. As shown in FIGS. 3A and 3B, the solder resist layer 14a is formed in the area surrounding the land part 4 directly below the metal plate 8. The solder resist layer 14a, being formed in the area where the metal plate 8 is situated, is removed by, for example, CMP (Chemical Mechanical Polishing), so that the metal plate 8 is prevented from contacting the solder resist layer 14a.

By covering substantially the entire area of the base substrate 2 with the solder resist layer 14a except for the area where the metal plate 8 is situated, the metal plate 8 can be easily positioned when bonding the metal plate 8 to the plating layer 6.

In a conventional case of bonding a metal plate to a land part by spot-welding, a nickel block is soldered onto a land part for increasing the bonding strength with respect to the metal plate, and then the metal plate is spot-welded onto the nickel block. Meanwhile, with reference to FIGS. 1A and 1B, in a case of bonding the metal plate 8 to the land part 4 by spot-welding according to an embodiment of the present invention, the surface of the land part 4 attains an improved bonding strength with respect to the metal plate 8 (e.g., being formed of nickel or a nickel alloy) and requires no soldering of a nickel block to the land part 4 due to the plating layer 6 formed on the surface of the land part 4. Furthermore, since nickel has a greater Young's modulus than copper, the breaking strength of the surface of the land part 4 can be improved. Thereby, the land part 4 can endure the stress caused by, for example, bending of a lead part of the metal plate 8.

It is to be noted that the surface of the plating layer 6 may be formed with a metal material besides nickel, such as chrome. That is, a metal material besides nickel may be used for the surface of the plating layer 6 as long as the metal material has a higher Young' modulus than a copper material (e.g., used in forming the circuit pattern) or an aluminum material and is able to achieve high bonding strength with respect to the metal plate 8.

With the above-described printed circuit board 100 according to an embodiment of the present invention, the process of bonding a lead terminal to the printed circuit board 100 can be automated since the bonding process can be simply achieved by the above-described spot-welding of the metal plate 8 (acting as the lead terminal) and without requiring any soldering. Furthermore, since no nickel block is necessary, manufacturing costs can be reduced.

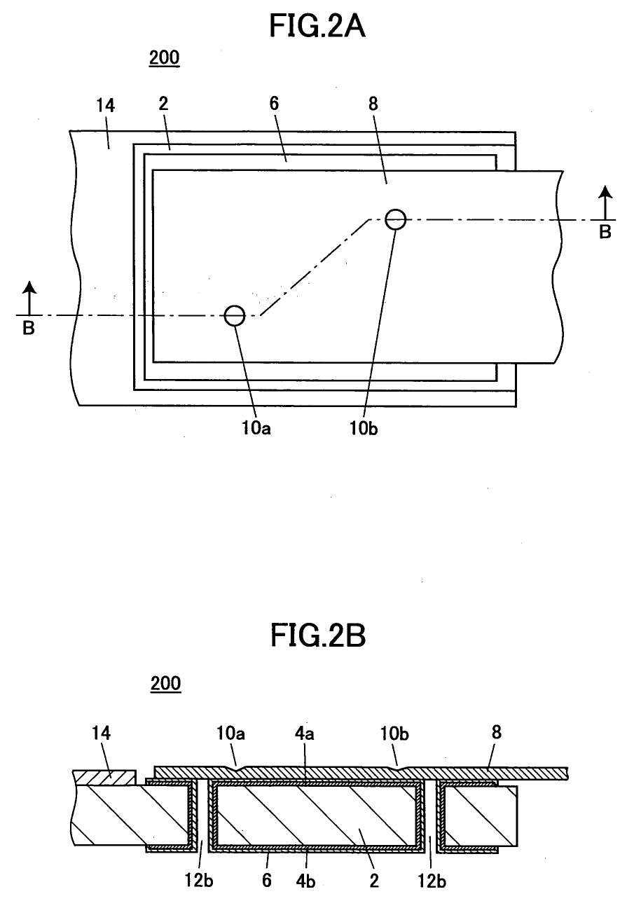

FIGS. 2A and 2B are drawings for describing a printed circuit board 200 according to a second embodiment of the present invention. FIG. 2A is a plan view of the printed circuit board 200 according to the second embodiment of the present invention. FIG. 2B is a cross-sectional view of the printed circuit board 200 according to the second embodiment of the present invention. In the printed circuit board 200 according to an embodiment of the present invention, a metal foil (e.g., copper) is laminated on an area corresponding to the front and back surfaces of a base substrate 2 and is patterned, to thereby form a circuit pattern and land parts 4a and 4b on the front and back surfaces of the base substrate 2. For the sake of convenience, only the land parts 4a and 4b are illustrated in FIGS. 2A and 2B and the circuit pattern is omitted.

The surface of the land parts 4a and 4b are covered by a plating layer 6. The plating layer 6 is formed, for example, by an electrolytic plating method or a non-electrolytic plating method. The plating layer 6 includes a gold plating layer and a nickel plating layer formed on the surface of the gold plating layer. It is to be noted that the plating layer 6 is illustrated as a single layer in FIGS. 2A and 2B for the sake of convenience. A metal plate 8 including, for example, nickel or a nickel alloy is bonded onto the plating layer 6 by spot-welding. The metal plate 8 bonded to the plating layer 6 acts as a lead terminal.

The base substrate 2 is formed with through-holes 12a and 12b in the vicinity of the areas (points) 10a, 10b on which spot-welding is performed. A plating layer is also formed in the inner walls of the through-holes 12a, 12b for electrically and mechanically connecting the land part 4a formed on the front surface side of the base substrate 2 and the land part 4b formed on the back surface side of the base substrate 2. The plating layer, which is formed on the inner walls of the through-holes 12a, 12b, is formed at the same time of forming the plating layer 6 on the surface of the land parts 4a and 4b.

A solder resist layer 14 having an opening(s) at the area(s) including the metal plate 8 is formed on the base substrate 2 for protecting the circuit pattern. In FIGS. 2A and 2B, the opening of the solder resist layer 14 not only contains (encompasses) the area including the metal plate 8 but also the area including the land part 4a and its surrounding area. As shown in FIG. 2A, the surface of the base substrate 2 is exposed at the area surrounding the plating layer 6 and the land part 4a where the metal plate 8 is not arranged (positioned).

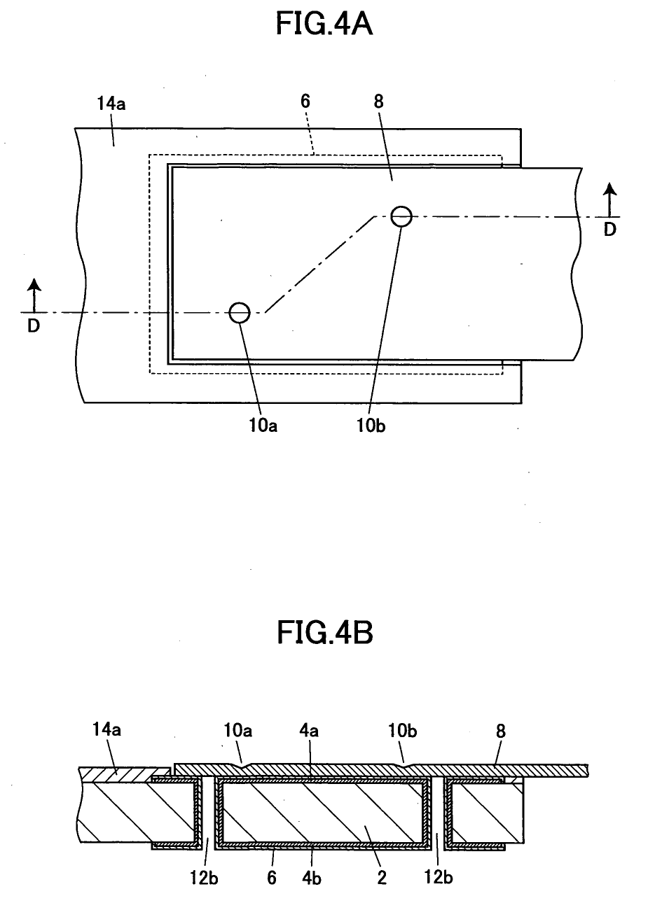

It is to be noted that a solder resist layer 14a according to another embodiment of the present invention may be formed in a manner covering substantially the entire area of the base substrate 2 except for the area where the metal plate 8 is situated, as shown in FIGS. 4A and 4B. The solder resist layer 14a according to this embodiment of the present invention can provide protection for the base substrate 2 and the land part 4a since the exposed areas of the base substrate 2 and the land part 4a can be reduced. Furthermore, since the solder resist layer 14a substantially covers the entire area of the base substrate 2 except for the area where the metal plate 8 is situated, the metal plate 8 can be easily positioned when bonding the metal plate 8 to the plating layer 6.

Next, the steps of fabricating the printed circuit board 200 of FIG. 2 according to an embodiment of the present invention are briefly described.

(1) Forming the circuit pattern and the land part 4a on the front surface side of the base substrate 2 and forming the land part 4b on the opposite side (rear surface side) with respect to the land part 4a formed on the front surface side.
(2) Forming the through-holes 12a and 12b in the vicinity of the areas (points) of the front surface of the base substrate 2 on which spot-welding is performed. The through-holes 12a, 12b may be, for example, BVH (Blind Via Holes) or flat through-holes. The through-holes 12a, 12b may be formed by, for example, a carbon dioxide (CO₂) gas laser or an excimer laser. Although the through-holes 12a, 12b may be formed by using a drill, it is preferable to form the through-holes 12a, 12b by using a laser beam capable of forming fine holes.
(3) Forming a copper plating layer on the surface of the land parts 4a, 4b and the inner walls of the through-holes 12a, 12b by an electrolytic plating method. In FIG. 2B, the copper plating layer 6 is illustrated in a manner integrated with the surface of the land parts 4a, 4b.
(4) Forming a gold plating layer on the copper plating layer formed on the surface of the land parts 4a, 4b and the inner walls of the through-holes 12a, 12b, and then forming a nickel plating layer on the gold plating layer. In FIG. 2B, the gold plating layer and the nickel plating layer are illustrated in an integrated manner, to thereby show a single plating layer 6.
(5) Forming a solder resist layer 14 on the area where the metal plate 8 is to be arranged (metal plate area) and the area besides the area surrounding the metal plate area.
(6) Bonding the metal plate 8 onto the land part 4a of the plating layer 6 by spot-welding.

In the above-described second embodiment of the present invention, by forming the through-holes 12a, 12b in the vicinity of the areas (points) on which spot-welding is performed for bonding the metal plate 8 and forming the same plating layer in the inner walls of the through-holes 12a, 12b as the copper plating layer and the plating layer (gold and nickel plating layer) 6 formed on the front and rear surfaces of the land parts 4a and 4b, the plating layer formed in the inner walls of the through-holes 12a, 12b mechanically connects the land part 4a on the front surface side and the land part 4b on the back surface side, so that the land part 4b can act as an anchor for increasing the peel strength between the land part 4a and the plating layer 6. It is to be noted that the through-holes 12a, 12b are not only formed for providing an anchor by mechanically connecting the land part 4a to the land part 4b on the back surface side. For example, the through-holes 12a, 12b may be used for drawing out a circuit pattern on the front surface or the rear surface in a case where the base substrate 2 is formed of plural layers having a circuit pattern(s) formed therein.

Although two through-holes are formed in the vicinity of the areas (points) 10a, 10b on which spot-welding is performed, the number of through-holes is not limited to two. For example, the number of the through-holes may be less than the number of areas (points) on which spot-welding is performed or greater than the number of areas (points) on which spot-welding is performed.

The present invention is not limited to the specifically disclosed embodiments, and variations and modifications may be made without departing from the scope of the present invention.

The present application is based on Japanese Priority Application No. 2007-011172 filed Jan. 22, 2007, the entire contents of which are hereby incorporated herein by reference.

1. A lead terminal bonding method comprising the steps of:
a) forming a land part on a front surface of a base substrate, the land part including a metal foil;
b) forming a metal plating layer on a surface of the land part, the metal plating layer having a Young's modulus greater than that of the metal foil; and
c) directly bonding a metal plate to the metal plating layer by spot-welding.

2. The lead terminal bonding method as claimed in claim 1, further comprising the steps of:
d) forming a second land part on a rear surface of the base substrate in a position corresponding to the land part formed on the front surface of the base substrate;
e) forming a through-hole between the land part and the second land part;
f) forming the metal plating layer on a surface of the second land part and an inner wall of the through-hole;
wherein steps d)-f) are performed before step c).

3. The lead terminal bonding method as claimed in claim 2, wherein the through-hole is situated in the vicinity of an area on which the spot-welding is performed.

4. The lead terminal bonding method as claimed in claim 1, wherein the metal plate includes at least nickel or a nickel alloy.

5. The lead terminal bonding method as claimed in claim 1, wherein the metal plating layer includes a nickel plating layer.

6. The lead terminal bonding method as claimed in claim 1, further comprising a step of:
forming a solder resist layer on the front surface of the base substrate before step c);
wherein the solder resist layer includes an opening part formed at least in an area where the metal plate is to be positioned.

7. A printed circuit board comprising:
a base substrate;
a land part formed on at least on a front surface of the base substrate, the land part including a metal foil;
a metal plating layer formed on a surface of the land part, the metal plating layer having a Young's modulus greater than that of the metal foil; and
a metal plate directly bonded to the metal plating layer by spot-welding.

8. The printed circuit board as claimed in claim 7, further comprising:
a second land part formed on a rear surface of the base substrate in a position corresponding to the land part formed on the front surface of the base substrate;
a through-hole situated between the land part and the second land part;
wherein the metal plating layer is further formed on a surface of the second land part and an inner wall of the through-hole.

9. The printed circuit board as claimed in claim 8, wherein the through-hole is situated in the vicinity of an area on which the spot-welding is performed.

10. The printed circuit board as claimed in claim 7, wherein the metal plate includes at least nickel or a nickel alloy.

11. The printed circuit board as claimed in claim 7, wherein the metal plating layer includes a nickel plating layer.

12. The printed circuit board as claimed in claim 7, further comprising:
a solder resist layer formed on the front surface of the base substrate;
wherein the solder resist layer includes an opening part formed at least in an area where the metal plate is positioned.
